(19) United States
(12) Patent Application Publication
(10) Pub. No.: US 2026/0324464 A1
(43) Pub. Date: Oct. 15, 2026

(54) VERTICAL-INTERCONNECT PACKAGING SUBSTRATE, FABRICATION METHOD, AND COPPER ELECTROPLATING METHOD FOR VIA FILLING

(71) Applicant: SUZHOU BOZHI JINZUAN TECHNOLOGY CO., LTD., Suzhou (CN)

(72) Inventors: Shixu JIN, Suzhou (CN); Yuanzhi PAN, Suzhou (CN); Xin LIU, Suzhou (CN)

(21) Appl. No.: 19/564,486

(22) Filed: Mar. 12, 2026

(30) Foreign Application Priority Data
Apr. 12, 2025 (CN) 202510456871.2

(51) Int. Cl. H10W 70/63; C23C 14/08; C23C 14/14; C23C 14/35; C23C 16/02; C23C 16/40; C23C 16/455; C23C 28/00; C25D 7/12; H10W 70/05

(52) U.S. Cl. CPC H10W 70/635; C23C 14/085; C23C 14/14; C23C 14/35; C23C 16/0245; C23C 16/405; C23C 16/45525; C23C 28/321; C23C 28/3455; C25D 7/123; H10W 70/095

(57) ABSTRACT

The present application provides a vertical-interconnect packaging substrate, a fabrication method, and a copper electroplating method for via filling. The fabrication method comprises forming a via in a substrate; forming a metal-oxide film layer on an inner wall of the via by atomic layer deposition; depositing a Ti/Cu seed layer on a surface of the metal-oxide film layer in the via and on a surface of the substrate by magnetron sputtering; depositing a reducing metal film layer on a surface of the seed layer in the via by magnetron sputtering, wherein the reducing metal film layer has a stronger reducing property than copper (Cu); and depositing an oxidizing film layer on the seed layer on the surface of the substrate by magnetron sputtering, wherein a reduction potential of metal ions of the oxidizing film layer is higher than that of copper ions (Cu²⁺), thereby achieving uniform void-free copper filling in deep vias.

### TECHNICAL FIELD

The present application belongs to the technical field of electronic packaging, and in particular relates to a vertical-interconnect packaging substrate, a fabrication method, and a copper electroplating method for via filling.

### BACKGROUND

With the rapid development of electronic devices toward high performance, high integration, and miniaturization, requirements for thermal conductivity, insulation, and mechanical stability of packaging substrates are increasingly stringent. Common packaging substrates, such as ceramic, glass, and organic plastic substrates, have been widely used in fields such as power modules, radio-frequency devices, and three-dimensional packaging. To realize multilayer circuit interconnection, enhanced heat dissipation, and high-frequency signal transmission, it is often necessary to fabricate deep-hole structures in packaging substrates and fill the deep-hole structures with metal (such as copper) to form vertical conductive vias. Meanwhile, metal patterns on the surface of the packaging substrate need to be precisely processed to construct high-precision circuits. However, the prior art still has significant technical bottlenecks in deep-hole copper filling, plating adhesion, and pattern alignment accuracy, which are specifically manifested as void defects in plated layers during deep-hole copper filling.

In a conventional via-filling electroplating process, due to the high aspect ratio (typically greater than 5:1) of the deep-hole structure, diffusion of an electroplating solution in the via is limited and current distribution is non-uniform. As a result, a current density at a via opening is significantly higher than that on the inner wall of the via, causing copper ions to preferentially deposit at the via opening, while deposition inside the via is slow, thereby readily forming micro-voids or seams in the via. Such defects can significantly reduce electrical conductivity, mechanical strength, and thermal conduction performance of the conductive via. The prior art attempts to improve via-filling performance through pulse electroplating, additive optimization (such as a brightener and a leveler), or gradient current regulation, but still lacks an effective solution for void-free filling of high aspect ratio vias on substrates (for example, with a depth greater than 500 μm and a via diameter less than 100 μm).

### SUMMARY

In order to solve the problems of voids and seams that are prone to occur in copper electroplating via filling of high aspect ratio vias on a packaging substrate due to non-uniform current distribution, the following technical solution is adopted.

A vertical-interconnect packaging substrate, comprising:
a substrate having at least one via formed therein;
a metal-oxide film layer deposited on an inner wall of the via, a Ti/Cu seed layer deposited on a surface of the metal-oxide film layer in the via and on a surface of the substrate, and a reducing metal film layer deposited on a surface of the Ti/Cu seed layer on the inner wall of the via, wherein the reducing metal film layer has a stronger reducing property than copper (Cu); and
an oxidizing film layer deposited on the Ti/Cu seed layer on the surface of the substrate, wherein a reduction potential of metal ions of the oxidizing film layer is higher than that of copper ions (Cu²⁺).

In a preferred solution, a material of the reducing metal film layer is selected from any one of: a Zn-Cu alloy, an Fe-Zn alloy, a Ni-Sn alloy, and an Al-Mg alloy.

In a preferred solution, the oxidizing film layer is selected from Fe₂O₃ or MoO₃.

In a preferred solution, a material of the substrate is selected from any one of ceramic, organic plastic, and glass.

In a preferred solution, the metal-oxide film layer is a titanium dioxide film layer having a thickness of 5-20 nm, and in the Ti/Cu seed layer, a Ti layer has a thickness of 100-120 nm and a Cu layer has a thickness of 1-3 μm; the reducing metal film layer is a Zn-Cu alloy film layer having a thickness of 100-300 nm, and the oxidizing film layer is an Fe₂O₃ film layer having a thickness of 100-300 nm.

The embodiments of the present application provide a method for fabricating the above vertical-interconnect packaging substrate, comprising the following steps: forming a via in a substrate, and forming a metal-oxide film layer on an inner wall of the via by atomic layer deposition;
depositing, by magnetron sputtering, a Ti/Cu seed layer on a surface of the metal-oxide film layer in the via and on a surface of the substrate;
depositing, by magnetron sputtering, a reducing metal film layer on a surface of the seed layer in the via, the reducing metal film layer having a stronger reducing property than copper (Cu);
depositing, by magnetron sputtering, an oxidizing film layer on the seed layer on the surface of the substrate, wherein a reduction potential of metal ions of the oxidizing film layer is higher than that of copper ions (Cu²⁺).

In a preferred solution, the vertical-interconnect packaging substrate uses pulse electroplating to fill the via. During copper electroplating via filling, an action mechanism of the reducing metal film layer on the inner wall of the via is as follows: taking a Zn-Cu alloy as an example, Zn has a stronger reducing property than Cu, and during the entire electroplating process, Zn can first react with Cu²⁺ according to: Zn+Cu²⁺→Zn²⁺+Cu; the displacement reaction accelerates copper deposition on the inner wall of the via and increases current density in the via.

The presence of the reducing metal film layer reduces a difference between deposition rates inside and outside the via, thereby preventing internal voids caused by excessively rapid growth of a copper layer at a via opening.

An action mechanism of the oxidizing film layer on an outer surface of the substrate is as follows: taking Fe₂O₃ as an example, metal ions of Fe₂O₃ have a reduction potential higher than that of Cu²⁺, and in a cathodic stage of electroplating, a reduction reaction preferentially occurs: Fe₂O₃+6H⁺+2e⁻→2Fe²⁺+3H₂O, thereby consuming electrons, suppressing copper deposition on the surface of the substrate, and causing a copper growth rate in the via to be significantly higher than that on the surface.

In a pulse electroplating via-filling process:
(1) when in a time interval of a forward current of a pulse power supply, the substrate is connected to a negative electrode of the power supply, that is, the substrate serves as a cathode, and since metal ions of the oxidizing film layer on the surface of the substrate have a reduction potential higher than that of copper ions (Cu²⁺), Fe₂O₃ preferentially undergoes a reduction reaction of Fe₂O₃+6H⁺+2e⁻→2Fe²⁺+3H₂O, thereby suppressing a growth rate of Cu on the surface of the substrate; meanwhile, since Cu²⁺ at the inner wall of the via has a stronger oxidizing property than Zn, a reduction reaction of Cu²⁺+2e⁻→Cu and a displacement reaction of Zn+Cu²⁺→Zn²⁺+Cu occur, thereby promoting a growth rate of Cu at the inner wall of the via.
(2) when in a time interval of a reverse current of the pulse power supply, the substrate is connected to a positive electrode of the power supply, that is, the substrate serves as an anode, and the substrate loses electrons and undergoes an oxidation reaction; at this time, since Cu on the surface of the substrate has a stronger reducing property than Fe²⁺, Cu preferentially undergoes an oxidation reaction of Cu-2e- →Cu²⁺, thereby consuming Cu on the surface of the substrate; meanwhile, since Zn at the inner wall of the via has a stronger reducing property than Cu, Zn preferentially undergoes an oxidation reaction of Zn−2e⁻→Zn²⁺ and a displacement reaction of Zn+Cu²⁺→Zn²⁺+Cu synchronously occurs, thereby limiting consumption of Cu at the inner wall of the via, such that a consumption rate of Cu at the inner wall of the via is far lower than a consumption rate of Cu on the surface of the substrate.

The present application achieves, through a synergistic effect of film layers, that the reducing metal film layer catalyzes reduction of Cu²⁺, accelerates copper growth on the inner wall of the via, promotes an in-via “bridging effect”, and reduces voids; and that the oxidizing film layer preferentially consumes electrons, reduces a surface copper deposition rate, causes the copper growth rate in the via to be greater than that on the surface, and avoids premature closure at a via opening, thereby realizing a technical effect of suppressed growth on the substrate surface and preferential deposition in the via; through the synergistic effect of film layers, voids in the via can be effectively avoided and complete metal filling in the via of the substrate can be achieved.

### BRIEF DESCRIPTION OF THE DRAWINGS

FIG. 1 is a schematic structural diagram of a vertical-interconnect packaging substrate according to an embodiment of the present application;

FIG. 2a is a schematic structural diagram of an X-shaped offset via on a substrate;

FIG. 2b is a schematic structural diagram of an hourglass via on a substrate;

FIG. 2c is a schematic structural diagram of a straight via on a substrate;

FIG. 2d is a schematic structural diagram of a tapered via on a substrate;

FIG. 3 is an optical microscopy test image after via filling by electroplating according to an embodiment of the present application;

FIG. 4 is an X-ray test image after via filling by electroplating according to an embodiment of the present application;

FIG. 5 is a schematic structural diagram of alignment holes and crosshair fiducial marks on a substrate according to an embodiment of the present application;

FIG. 6 is a schematic diagram of redox reactions during a pulse electroplating via-filling process when the substrate serves as a cathode according to an embodiment of the present application; and

FIG. 7 is a schematic diagram of redox reactions during a pulse electroplating via-filling process when the substrate serves as an anode according to an embodiment of the present application.

### DETAILED DESCRIPTION

In order to make the objectives, technical solutions, and advantages of the present application more clear, the present application will be further described in detail below with reference to the accompanying drawings.

### Embodiment 1

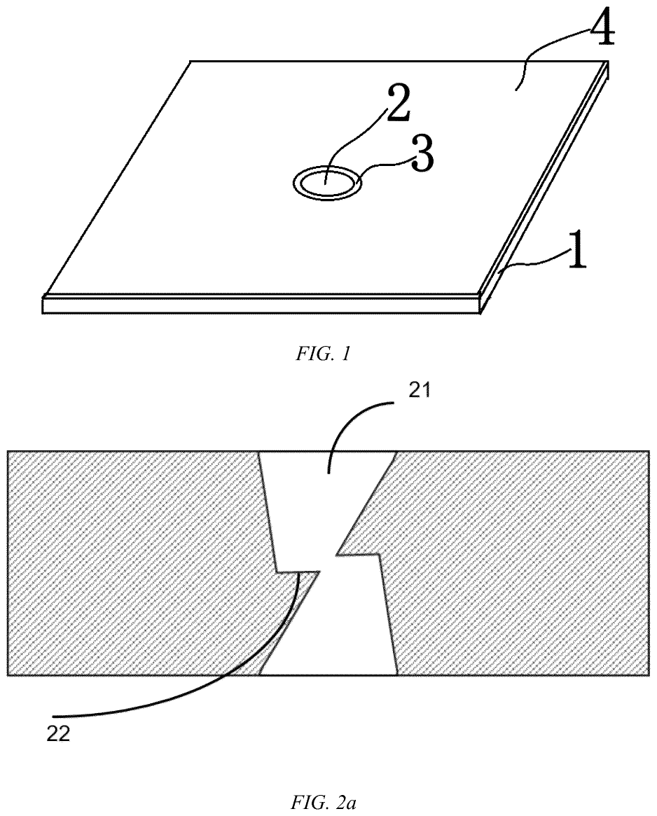

A vertical-interconnect packaging substrate, as shown in FIG. 1, comprises: a substrate 1 having at least one via 2 formed therein; a metal-oxide film layer deposited on an inner wall of the via 2, a Ti/Cu seed layer deposited on a surface of the metal-oxide film layer on the inner wall of the via 2 and on a surface of the substrate, and a reducing metal film layer 3 deposited on a surface of the Ti/Cu seed layer on the inner wall of the via 2, wherein the reducing metal film layer 3 has a stronger reducing property than copper (Cu); and an oxidizing film layer 4 deposited on the Ti/Cu seed layer on the surface of the substrate, wherein a reduction potential of metal ions of the oxidizing film layer is higher than that of copper ions (Cu²⁺). FIG. 1 is only used to show a positional relationship among the substrate 1, the via 2, the reducing metal film layer 3, and the oxidizing film layer 4, and the metal-oxide film layer and the Ti/Cu seed layer deposited on the inner wall of the via are not drawn or labeled in FIG. 1.

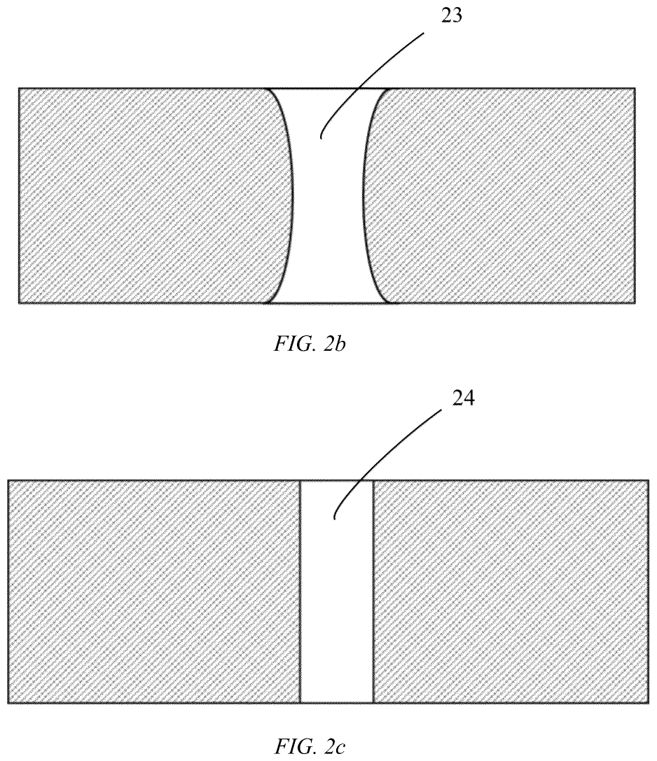

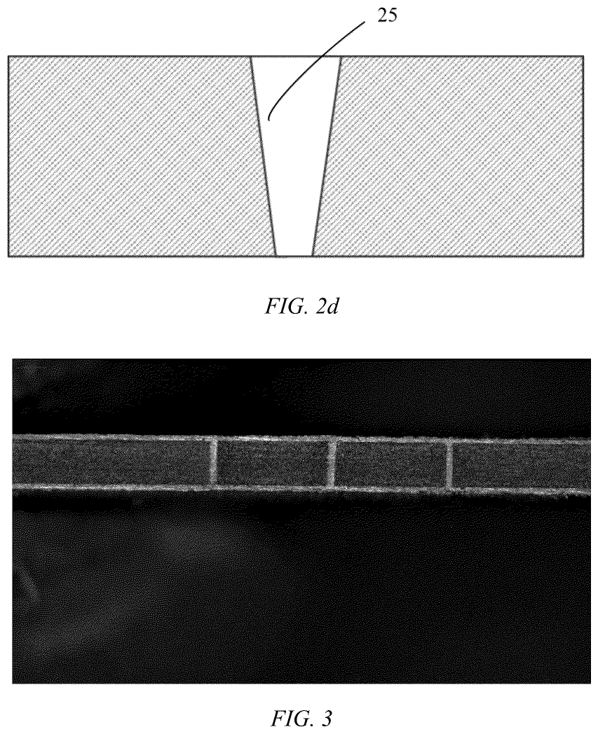

In another embodiment, as shown in FIG. 2a, the via is an offset via 21. The X-shaped offset via can be formed by offset ablation performed on two sides of the substrate 1 using an excimer laser (cold laser), to form the X-shaped offset via as shown in FIG. 2a, and the via has a bending portion 22 in a middle thereof. In a subsequent copper electroplating via-filling process, the bending portion 22 (also referred to as a turning) in the middle of the via has a high current density, and a Cu growth rate in the middle of the via is high, which is conducive to via filling.

As a variation of the embodiment of FIG. 2a, as shown in FIG. 2b, the via is an hourglass via 23. As a variation of the embodiment of FIG. 2a, as shown in FIG. 2c, the via is a straight via 24. As a variation of the embodiment of FIG. 2a, as shown in FIG. 2d, the via is a tapered via 25.

### Embodiment 2

A vertical-interconnect packaging substrate comprises a substrate, wherein a material of the substrate is selected from ceramic, and at least one via is formed in the substrate; a reducing metal film layer is further deposited on an inner wall surface of the via, wherein the reducing metal film layer is a Zn-Cu alloy film layer having a thickness of 100-300 nm; and an oxidizing film layer is deposited on an outer surface of the substrate, wherein the oxidizing film layer is an Fe₂O₃ film layer having a thickness of 100-300 nm.

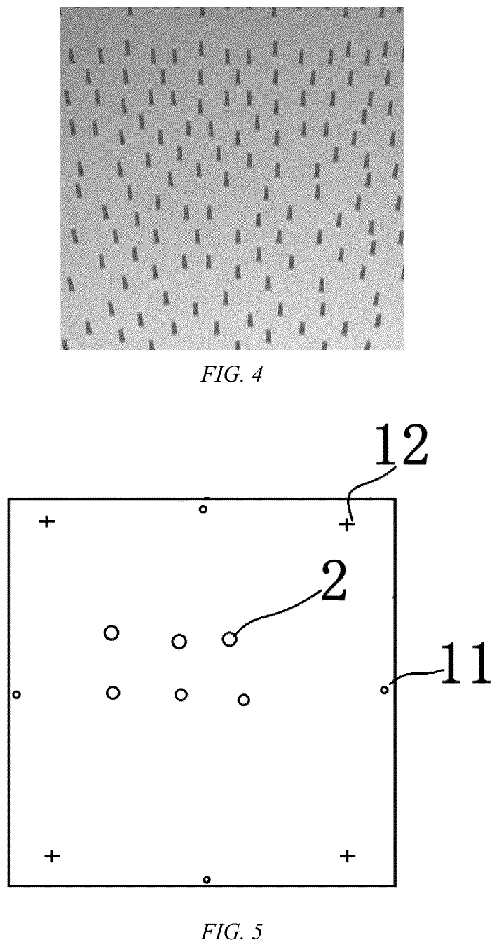

After copper electroplating via filling using the packaging substrate of this embodiment, an optical microscopy image is as shown in FIG. 3, and an X-ray image is as shown in FIG. 4.

FIG. 3 shows an optical microscopy test performed on a cross-sectional slice of the substrate after electroplating Cu via filling is completed, and it can be seen that the via is filled with Cu without voids; FIG. 4 shows an X-ray test performed on the substrate after electroplating Cu via filling is completed, and it can be seen that the via is filled with Cu without voids and a Cu layer is uniform and dense.

### Embodiment 3

A vertical-interconnect packaging substrate comprises a substrate, wherein a material of the substrate is selected from glass; a metal-oxide film layer is deposited on an inner wall of a via of the substrate, a Ti/Cu seed layer is deposited on a surface of the metal-oxide film layer deposited on the inner wall of the via and on a surface of the substrate, and a reducing metal film layer is deposited on a surface of the Ti/Cu seed layer on the inner wall of the via; and an oxidizing film layer is deposited on the Ti/Cu seed layer on the surface of the substrate. Preferably, the metal-oxide film layer is a titanium dioxide film layer having a thickness of 5-20 nm; in the Ti/Cu seed layer, a Ti layer has a thickness of 100-120 nm and a Cu layer has a thickness of 1-3 μm; the oxidizing film layer is a molybdenum trioxide film layer having a thickness of 100-300 nm; and the reducing metal film layer is an Al-Mg alloy film layer having a thickness of 100-300 nm.

The Al-Mg alloy of the reducing metal film layer increases current density in the via through displacement reactions and catalytic effects, thereby accelerating deposition of copper ions on the inner wall of the via.

The Ti/Cu seed layer is provided to ensure uniform copper deposition, and the titanium dioxide film layer enhances adhesion and prevents peeling of a plated layer. The molybdenum trioxide oxidizing film layer preferentially consumes electrons and interferes with a reduction rate of copper ions, thereby suppressing deposition of copper at a via opening on an outer surface of the substrate. This suppression effect avoids excessively rapid growth of a copper layer at the via opening and prevents premature closure of the via opening and formation of voids.

### Embodiment 4

A vertical-interconnect packaging substrate comprises a substrate, wherein a material of the substrate is organic plastic, and at least one via is formed in the substrate; a reducing metal film layer is further deposited on an inner wall surface of the via, wherein the reducing metal film layer has a stronger reducing property than copper (Cu); and an oxidizing film layer is deposited on an outer surface of the substrate, wherein a reduction potential of metal ions of the oxidizing film layer is higher than that of copper ions (Cu²⁺); a material of the reducing metal film layer is selected from any one of: a Zn-Cu alloy, an Fe-Zn alloy, a Ni-Sn alloy, and an AI-Mg alloy, and the oxidizing film layer is selected from Fe₂O₃ or MoO₃.

The reducing film layer on the inner wall of the via increases current density in the via through displacement and catalytic effects, thereby accelerating deposition of copper ions on the inner wall of the via.

### Embodiment 5

As a preferred solution based on Embodiment 1, as shown in FIG. 5, the vertical-interconnect packaging substrate comprises a substrate, and alignment holes 11 and a plurality of crosshair fiducial marks 12 are provided on the substrate.

For a substrate having a thickness of 0.1-5 mm, a straight via is fabricated using a laser at an aspect ratio of 20:1, and alignment holes and a plurality of crosshair fiducial marks having different sizes are fabricated on both sides of the substrate for alignment in a subsequent substrate-surface circuit patterning process.

An alignment method during exposure is as follows: placing the substrate coated with photoresist or attached with a dry film and a corresponding mask plate at corresponding positions of an exposure machine, fixing the mask plate, adjusting a position of the substrate such that the crosshair fiducial marks/alignment holes on the substrate completely overlap with the crosshair fiducial marks/alignment holes on the mask plate, moving a viewing angle to a position of a next crosshair fiducial mark or alignment hole, and continuing adjustment until all crosshair fiducial marks and alignment holes having different sizes on the substrate completely overlap with those on the mask plate. With this method, alignment accuracy can be controlled within ±1 μm.

### Embodiment 6

A method for fabricating a vertical-interconnect packaging substrate comprises the following steps:
forming a via in a substrate;
depositing, by magnetron sputtering, a reducing metal film layer on a surface of a seed layer in the via, wherein the reducing metal film layer has a stronger reducing property than copper (Cu); and
depositing, by magnetron sputtering, an oxidizing film layer on an outer surface of the seed layer of the substrate, wherein a reduction potential of metal ions of the oxidizing film layer is higher than that of copper ions (Cu²⁺).

In some more detailed specific examples, the method for fabricating the vertical-interconnect packaging substrate comprises forming a via in a substrate; performing a roughening treatment on an inner wall of the via, and increasing roughness through plasma etching and UV cleaning; forming, by atomic layer deposition, a titanium dioxide metal-oxide film layer on the inner wall of the via; depositing, by magnetron sputtering, a Ti/Cu seed layer on a surface of the metal-oxide film layer and on a surface of the substrate; depositing, by magnetron sputtering, a Zn-Cu alloy reducing metal film layer on a surface of the seed layer in the via; and depositing, by magnetron sputtering, an Fe₂O₃ oxidizing film layer on an outer surface of the seed layer of the substrate.

Specific steps of performing the roughening treatment on the inner wall of the via comprise:
(1) spin coating photoresist: placing the substrate on a spin coater, pouring an appropriate amount of photoresist, then starting at a low speed (typically 500-1000 rpm) for pre-spin coating, and then gradually increasing the speed to 2000-4000 rpm and maintaining for tens of seconds (e.g., 50 s), so that the photoresist is uniformly distributed on the surface of the substrate.
(2) soft bake: after spin coating, placing the substrate into an oven for soft bake, typically baking at 80 °C to 120 °C for 1 to 10 minutes to remove a solvent in the photoresist.
(3) exposure: placing the substrate coated with photoresist or attached with a dry film and a corresponding mask plate at a corresponding position of an exposure machine, fixing the mask plate, adjusting a position of the substrate such that crosshair fiducial marks/alignment holes on the substrate completely overlap with crosshair fiducial marks/alignment features on the mask plate, moving a viewing angle to a position of a next crosshair fiducial mark/alignment hole, continuing adjustment until all crosshair fiducial marks and alignment holes having different sizes on the substrate completely overlap with those on the mask plate, and then performing exposure for 1-30 s. With this method, alignment accuracy can be controlled within ±1 μm.
(4) development: performing development on the exposed substrate using a developer, and photoresist on the inner wall of the via or on the surface of the substrate is removed.
(5) after development, the photoresist on the inner wall of the via is removed while the photoresist on the surface still exists, performing UV cleaning at a wavelength of 254 nm on the inner wall of the via and performing plasma etching on the inner wall of the via, while the surface of the substrate is protected by the photoresist and is not etched, thereby increasing only roughness of the inner wall of the via, which is conducive to improving current density and plating adhesion on the inner wall of the via in a subsequent copper electroplating via-filling process.

In one embodiment, depositing a metal-oxide film layer on an inner wall of a via comprises the following steps:
(1) atomic layer deposition of the metal-oxide film layer: Ti(OPr)₄ and H₂O₂ are respectively introduced into a reactor in a pulse form using high-purity nitrogen as a carrier gas; at 60 °C, a vapor pressure of Ti(OPr)₄ is maintained at about 6.6 Pa, and an inert gas purge state is maintained between two pulses, so as to clean byproducts and molecules that are not chemically adsorbed on a surface; a metal-oxide TiO₂ film layer is deposited on the inner wall of the via, and the film layer can improve bonding force between a subsequent plated layer and a substrate through a nanoscale mechanical pinning effect.
(2) removing photoresist: at room temperature, ultrasonic cleaning is performed in a dedicated photoresist stripping solution at 80 kHz for 10 min to remove photoresist on a surface of the substrate.

Depositing a seed layer on the surface of the substrate and on the inner wall of the via comprises: sputtering for 30-40 min under conditions of a vacuum degree of 0.2-0.5 Pa, a bias voltage of −100 V to −60 V, a substrate temperature of 100-200 °C, and a sputtering power of 5-8 kW, to deposit a Ti layer having a thickness of 100-120 nm; and sputtering for 30-300 min under conditions of a vacuum degree of 0.1-0.5 Pa, a bias voltage of −50 V to −200 V, a substrate temperature of 25-300 °C, and a sputtering power of 1-15 kW, to deposit a Cu layer having a thickness of 1-10 μm.

Depositing a Zn-Cu alloy reducing metal film layer on the inner wall of the via comprises the following steps:
(1) coating photoresist on the surface of the substrate by spin coating, soft bake, exposure, and development, and removing photoresist in the via by development.
(2) using a Zn-Cu alloy target, sputtering for 10-30 min under conditions of a vacuum degree of 0.1-0.5 Pa, a bias voltage of −50 V to −200 V, a substrate temperature of 25-300 °C, and a sputtering power of 1-5 kW, to deposit a Zn-Cu alloy layer having a thickness of 100-300 nm on a surface of the seed layer in the via.
(3) removing photoresist: at room temperature, ultrasonic cleaning is performed in a dedicated photoresist stripping solution at 80 kHz for 10 min to remove photoresist on the surface of the substrate.

Depositing an Fe₂O₃ oxidizing film layer on an outer surface of the substrate comprises the following steps:
(1) coating photoresist on the inner wall of the via by spin coating, soft bake, exposure, and development, and removing photoresist on the surface of the substrate by development.
(2) using an Fe₂O₃ target, RF sputtering for 20-40 min under conditions of a vacuum degree of 0.1-0.5 Pa, a bias voltage of −50 to −150 V, a substrate temperature of 100-300 °C, and an RF sputtering power of 2-7 kW, to deposit an iron oxide layer having a thickness of 100-300 nm on the surface of the substrate.
(3) removing photoresist: at room temperature, ultrasonic cleaning is performed in a dedicated photoresist stripping solution at 80 kHz for 10 min to remove photoresist on the inner wall of the via.

### Embodiment 7

A copper electroplating method for via filling using a vertical-interconnect packaging substrate is provided, wherein the method uses pulse electroplating to fill vias, a reducing metal film layer in the method is a Zn-Cu alloy film layer, and an oxidizing film layer is an Fe₂O₃ film layer.

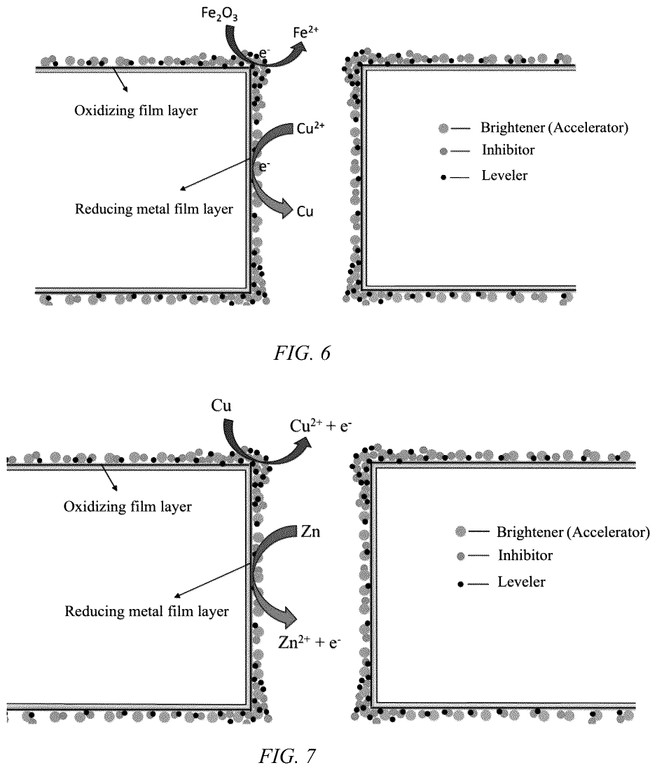

An electroplating solution is composed of 200-250 g/L CuSO₄·₅H₂O, 50-100 g/L H₂SO₄, and 20-100 mg/L Cl., wherein copper electroplating additives include a leveler, a brightener, and an inhibitor; the brightener includes PEG (polyethylene glycol) at a concentration of 1-5 g/L for promoting copper deposition and refining grains; the inhibitor includes SPS (sodium thiosulfate) at a concentration of 1-5 mg/L for increasing cathodic polarization and reducing surface tension; and the leveler comprises Janus Green B at a concentration of 0.1-1 mg/L for suppressing copper deposition in a high current density region; FIG. 6 is a schematic diagram of redox reactions occurring on a substrate surface and on an inner wall of a via when the substrate serves as a cathode during a pulse electroplating via-filling process; the brightener (accelerator) in the electroplating solution can accelerate deposition of Cu²⁺, and the brightener tends to accumulate at a position with a large curvature, and as bridging is gradually formed at a middle position of the via and curvature increases, the brightener tends to accumulate at the middle position of the via to accelerate Cu²⁺ deposition at the middle position of the via, which is conducive to filling of the via; the inhibitor and the leveler tend to accumulate at a via opening and suppress Cu²⁺ deposition, so that a Cu growth rate at the via opening is lower than a Cu growth rate in the via, which is conducive to filling inside the via; the inner wall of the via has a reducing metal film layer, and during electroplating Cu via filling, the reducing metal can reduce Cu²⁺ in the solution to Cu to attach on a surface, and can also increase an exchange rate of Cu²⁺ near an inner region of the via, thereby accelerating a deposition rate of Cu²⁺ at a middle position inside the via; and an oxidizing film layer is provided outside/at the via opening, and during electroplating Cu via filling, the oxidizing film layer preferentially discharges relative to Cu²⁺, thereby reducing a deposition rate of Cu²⁺ outside/at the via opening.

FIG. 7 is a schematic diagram of redox reactions occurring on a substrate surface and on an inner wall of a via when the substrate serves as an anode during a pulse electroplating via-filling process, wherein surface Cu preferentially undergoes an oxidation reaction relative to Fe²⁺, and Zn in the via preferentially undergoes an oxidation reaction.

During electroplating, a forward-to-reverse current ratio is controlled to be 2:1-4:1, a forward-to-reverse time ratio is 8:1-80:1, and current density is 1-4 ASD (A/dm²).

In a pulse electroplating via-filling process:
(1) when in a time interval of a forward current, the substrate serves as a cathode, obtains electrons, and undergoes a reduction reaction; at this time, since the oxidizing film layer on the surface of the substrate is Fe₂O₃ and has a stronger oxidizing property than Cu²⁺, Fe₂O₃ preferentially undergoes a reduction reaction of Fe₂O₃+6H⁺+2e⁻→2Fe²⁺+3H₂O, thereby suppressing a growth rate of Cu on the surface of the substrate; meanwhile, since Cu²⁺at the inner wall of the via has a stronger oxidizing property than Zn, a reduction reaction of Cu²⁺+2e⁻→Cu and a displacement reaction of Zn+Cu²⁺→Zn²⁺+Cu occur, thereby promoting a growth rate of Cu at the inner wall of the via.
(2) when in a time interval of a reverse current, the substrate serves as an anode, loses electrons, and undergoes an oxidation reaction; at this time, since surface Cu has a stronger reducing property than Fe²⁺, Cu preferentially undergoes an oxidation reaction of Cu-2e⁻→Cu²⁺, thereby consuming Cu on the surface of the substrate; meanwhile, since Zn at the inner wall of the via has a stronger reducing property than Cu, Zn preferentially undergoes an oxidation reaction of Zn-2e⁻→Zn²⁺, thereby limiting consumption of Cu at the inner wall of the via, such that a consumption rate of Cu at the inner wall of the via is far lower than a consumption rate of Cu on the surface of the substrate.

The oxidizing film layer on the surface of the substrate and the reducing metal film layer in the via can effectively promote a copper growth rate in the via and reduce a copper growth rate on the surface of the substrate.

### Embodiment 8

A method for preparing a pattern on a surface of a vertical-interconnect packaging substrate comprises the following steps:
S1. forming a via, alignment holes, and crosshair fiducial marks on a substrate using a laser;
S2. spin coating photoresist on the surface of the substrate and inside the via, and then performing soft bake in an oven;
aligning the substrate with a corresponding mask plate using the alignment holes and the crosshair fiducial marks, and then performing exposure and development, at which time the photoresist in the via is dissolved or removed while the photoresist on the surface of the substrate remains intact;
then performing roughening treatment on an inner wall of the via using a laser to increase roughness of the inner wall; this step can improve plating adhesion of a subsequent film layer and increase current density on the inner wall during a subsequent copper electroplating via-filling process, so that an electroplated copper growth rate is faster and is conducive to filling the via;
S3. depositing a metal-oxide film layer on the inner wall of the via by atomic layer deposition, wherein a material of the metal-oxide film layer is selected from any one of titanium dioxide, indium gallium zinc oxide, and indium tin oxide;
then removing the photoresist on the surface of the substrate using a dedicated stripping solution;
S4. depositing a seed layer on the surface of the substrate and on a surface of the via, wherein in this step, the seed layer is deposited on the surface of the substrate and on the surface of the via by magnetron sputtering;
S5. spin coating photoresist on the surface of the substrate and inside the via, and then performing soft bake in an oven;
aligning the substrate with a corresponding mask plate using the alignment holes and the crosshair fiducial marks, and then performing exposure and development, at which time the photoresist in the via is dissolved or removed while the photoresist on the surface of the substrate remains intact;
placing the substrate into a plasma etching machine, and precisely removing residual photoresist in the via through a physical or chemical reaction of plasma without damaging the surface or formed structures;
S6. depositing a reducing metal film layer on a surface of the seed layer in the via by magnetron sputtering, wherein in this step, a reducing metal film layer is deposited on a surface of a Cu seed layer in the via by magnetron sputtering; in a subsequent copper electroplating via-filling process, the reducing metal film layer can directly displace copper ions to accelerate growth of a Cu layer on the inner wall, which is conducive to filling of the Cu layer in the via; meanwhile, ion concentration at the inner wall can be increased to increase current density there, which is conducive to growth and deposition of the Cu layer there during electroplating;

S7. spin coating photoresist on the surface of the substrate and inside the via, and then performing soft bake in an oven;
aligning the substrate with a corresponding mask plate using the alignment holes and the crosshair fiducial marks, and then performing exposure and development, at which time the photoresist on the surface of the substrate is dissolved or removed while the photoresist on the inner wall of the via remains intact;
S8 . depositing an oxidizing film layer on the surface of the substrate by magnetron sputtering, wherein the oxidizing film layer preferentially discharges relative to copper ions; the oxidizing film layer provided is gradually consumed during copper electroplating; for example, an Fe₂O₃ film layer preferentially discharges relative to copper ions, and Fe₂O₃ obtains electrons to generate Fe²⁺, thereby reducing a deposition rate of copper ions on the surface of the substrate, thereby avoiding a problem that copper growth outside/at the via opening is faster than copper growth on the inner wall of the via;
then removing the photoresist on the inner wall of the via using a dedicated stripping solution;

S9. preparing a pattern on the surface of the substrate through a dry film, exposure, and development, comprising the following steps:
(1) dry film pretreatment: spray rinsing with pure water and drying, wherein a line speed is 5 m/min, a spray pressure is 1-3 kg/cm², and a drying temperature is 100 °C.
(2) dry film lamination: a pressure is 1-4 kg/cm², a speed is 1-1.5 m/min, and a temperature is 80-90 °C.
(3) exposure: placing the substrate attached with the dry film and a corresponding mask plate at a corresponding position of an exposure machine, fixing the mask plate, adjusting a position of the substrate such that crosshair fiducial marks/alignment holes on the substrate completely overlap with crosshair fiducial marks/alignment features on the mask plate, moving a viewing angle to a position of a next crosshair fiducial mark/alignment hole, continuing adjustment until all crosshair fiducial marks and alignment holes having different sizes on the substrate completely overlap with those on the mask plate, and then performing exposure for 20-40 s; with this method, alignment accuracy can be controlled within ±1 μm.
(4) development: performing development using a dedicated dry-film developer at a temperature of 30-40 °C, a speed of 2-5 m/min, and a spray pressure of 1-3 kg/cm².
S10. filling the via with copper by pulse electroplating; during electroplating, using a jig to place the substrate into an electroplating bath, slowly moving the substrate up and down using the jig during electroplating to avoid non-uniform composition of the electroplating solution due to excessive consumption of the electroplating solution in a small region, and using ultrasonic vibration during electroplating to uniformly distribute components of the electroplating solution; and installing spray nozzles around the electroplating bath to spray the electroplating solution so that components of the electroplating solution are uniformly mixed.
S11. forming an Ni/Pd/Au layer on the surface of the substrate by electroless plating, comprising the following steps:
(1) stripping: removing the dry film using a dedicated dry-film stripping solution at a temperature of 30-40 °C, a speed of 2-5 m/min, and a spray pressure of 1-3 kg/cm².
(2) etching: etching copper and a Ti seed layer using sodium persulfate and hydrofluoric acid, respectively, at a temperature of 30-40 °C, a speed of 2-5 m/min, and a spray pressure of 1-3 kg/cm².
(3) electroless Ni plating: at a temperature of 80-95 °C, a nickel ion concentration of 2.6-3.3 g/L, a pH controlled at 5.2-6.1, and a time of 10-50 min, and an Ni thickness of 3-6 μm.
(4) electroless Pd plating: a palladium salt concentration of 0.5-2 g/L, a temperature of 50-70 °C, a pH controlled at 4.0-7.0, a time of 10-40 min, and a Pd thickness of 0.07-0.3 μm.
(5) electroless Au plating: a KAu(CN)₂ concentration of 1-3 g/L, a temperature of 80-95 °C, a pH controlled at 4.0-6.0, a time of 20-60 min, and an Au thickness of 0.3-0.6 μm.

The present application realizes a technical solution for void-free copper filling through substrate-surface modification, a synergistic effect of film layers, and a pulse electroplating process. The present application is applicable to electronic device fields with stringent requirements on electrical performance and thermal management, such as high-frequency radio-frequency devices, power modules, and three-dimensional integrated packaging. First, vias are formed in the substrate and an inner wall is etched to increase roughness; a metal-oxide film layer is formed on the inner wall of the via by atomic layer deposition to improve bonding of a seed layer; then a Ti/Cu seed layer is deposited by magnetron sputtering, and a metal film layer having a stronger reducing property than copper is selectively sputtered in the via, and an oxidizing film layer is sputtered on the surface of the substrate; in combination with pulse electroplating, reduction of metal ions of the oxidizing film layer preferentially occurs to suppress copper deposition on the surface of the substrate, while the reducing metal film layer promotes rapid deposition of copper ions in the via, thereby realizing uniform copper filling in deep vias. Through alignment calibration using the alignment hole and the crosshair fiducial marks, pattern accuracy reaches ±1 μm. This method effectively improves density and adhesion of a plated layer in the via, avoids premature closure at a via opening and formation of voids, and is suitable for high-precision patterned packaging fabrication of high aspect ratio substrates.

The foregoing embodiments are merely intended to illustrate the technical concept and features of the present application, so that those skilled in the art can understand the content of the present application and implement the present application, and are not intended to limit the scope of protection of the present application. Any modifications made based on the spirit and essence of the main technical solutions of the present application shall fall within the scope of protection of the present application.

1. A vertical-interconnect packaging substrate, comprising:
a substrate having at least one via formed therein;
a metal-oxide film layer deposited on an inner wall of the via, a Ti/Cu seed layer deposited on a surface of the metal-oxide film layer in the via and on a surface of the substrate, and a reducing metal film layer deposited on a surface of the Ti/Cu seed layer on the inner wall of the via; and
an oxidizing film layer deposited on the Ti/Cu seed layer on the surface of the substrate, wherein the reducing metal film layer has a stronger reducing property than copper (Cu), and a reduction potential of metal ions of the oxidizing film layer is higher than that of copper ions (Cu²⁺).

2. The vertical-interconnect packaging substrate of claim 1, wherein
a material of the reducing metal film layer is selected from any one of: a Zn-Cu alloy, an Fe-Zn alloy, a Ni-Sn alloy, and an Al-Mg alloy, and the oxidizing film layer is selected from Fe₂O₃ or MoO₃.

3. The vertical-interconnect packaging substrate of claim 1, wherein the via comprises one of an offset via, an hourglass via, a tapered via, or a straight via.

4. The vertical-interconnect packaging substrate of claim 1, wherein the substrate is provided with alignment holes and a plurality of crosshair fiducial marks.

5. The vertical-interconnect packaging substrate of claim 1, wherein
the metal-oxide film layer is a titanium dioxide film layer having a thickness of 5-20 nm; in the Ti/Cu seed layer, a Ti layer has a thickness of 100-120 nm and a Cu layer has a thickness of 1-3 μm; the reducing metal film layer is a Zn-Cu alloy film layer having a thickness of 100-nm; and the oxidizing film layer is an Fe₂O₃ film layer having a thickness of 100-300 nm.

6. The vertical-interconnect packaging substrate of claim 1, wherein
a material of the substrate is selected from any one of ceramic, organic plastic, and glass.

7. A method for fabricating the vertical-interconnect packaging substrate of claim 1, comprising:
forming a via in a substrate, and forming a metal-oxide film layer on an inner wall of the via by atomic layer deposition;
depositing, by magnetron sputtering, a Ti/Cu seed layer on a surface of the metal-oxide film layer in the via and on a surface of the substrate;
depositing, by magnetron sputtering, a reducing metal film layer on a surface of the seed layer in the via, the reducing metal film layer having a stronger reducing property than copper (Cu); and
depositing, by magnetron sputtering, an oxidizing film layer on the seed layer on the surface of the substrate, wherein a reduction potential of metal ions of the oxidizing film layer is higher than that of copper ions (Cu²⁺).

8. The method of claim 7, wherein
the forming a via in a substrate and forming a metal-oxide film layer on an inner wall of the via by atomic layer deposition comprises:
forming the via in the substrate, and providing alignment holes and crosshair fiducial marks on both sides of the substrate; and
performing plasma etching and UV cleaning on the inner wall of the via to increase roughness;
forming a titanium dioxide metal-oxide film layer on the inner wall of the via by atomic layer deposition.

9. The method of claim 7, wherein
the depositing, by magnetron sputtering, a Ti/Cu seed layer on a surface of the metal-oxide film layer in the via and on a surface of the substrate comprises:
depositing, by magnetron sputtering, the Ti/Cu seed layer on the surface of the metal-oxide film layer in the via and on the surface of the substrate;
depositing, by magnetron sputtering, a Zn-Cu alloy reducing metal film layer on a surface of the Ti/Cu seed layer in the via; and
depositing, by magnetron sputtering, an oxidizing film layer on the Ti/Cu seed layer on the surface of the substrate.

10. A copper electroplating method for via filling using the vertical-interconnect packaging substrate of claim 1, wherein pulse electroplating is used to fill the via.
